(19) United States
(12) Patent Application Publication
(10) Pub. No.: US 2005/0159006 A1
(43) Pub. Date: Jul. 21, 2005

(54) Method of forming electrical connection means of ultimate dimensions and device comprising such connection means

(76) Inventor: Willem Jan Toren, Crolles (FR)

Correspondence Address: Philips Electronics North America Corporation;Intellectual Property & Standards, 1109 McKay Drive, M/S41-SJ, San Jose, CA, 95131, US

(21) Appl. No.: 10/505,287

(22) PCT Filed: Feb. 12, 2003
(86) PCT No.: PCT/IB03/00543

(30) Foreign Application Priority Data
Feb. 21, 2002 (EP) 02290430.4

(51) Int. Cl. H01L 21/311

(52) U.S. Cl. 438/696

(57) ABSTRACT

The invention relates to a method of forming electrical connection means on a substrate, which method comprises the following steps:
a) depositing an intermediate layer of material (14) on a substrate (10), b) forming an etching mask having at least one window, c) etching the layer of intermediate material in conformity with the mask in order to form at least one aperture therein,
d) coating the lateral side-walls of the aperture with a spacer (22) in order to narrow the aperture,
e) depositing at least one conductor material (24) so as to fill the narrowed aperture, and f) performing an abrasion operation so as to remove excess conductor material outside the aperture. The invention is used for the realization of wiring tracks, contact pads and vias.

The invention relates to a method of forming electrical connection means of “ultimate” dimensions and to a device comprising such connection means. “Ultimate” dimensions are to be understood to mean dimensions which are smaller than those that can be achieved by the photolithography techniques usually carried out for fixing the pattern and the dimensions of microelectronic components or circuits. For example, a part of a component is considered to have an ultimate dimension if at least one of its dimensions, for example, a length, a width or a diameter, is less than 0.1 μm.

The invention can be used for the realization of electronic circuits and notably for the realization of highly integrated CMOS circuits (complementary metal oxide semiconductor circuits). It can be used particularly advantageously for the realization of connection means such as a contact pad, a conductor track or a via between layers.

The realization of contact pads in the field of microelectronics includes the deposition of a layer of a conductive material which is to be electrically contacted by a part of a component or a circuit. This layer is subsequently shaped by means of photolithography techniques which are known per se.

Japanese document JP-A-10150104 describes a method of forming a via. The via is covered with a layer of polycrystalline silicon so as to reduce the diameter thereof. This layer is subsequently oxidized. The cited document, even though it envisages a reduction of the diameter of a via, does not enable a substantial reduction of the overall dimensions of the contact on the surface of the substrate. Moreover, the oxidation step for the layer of polycrystalline silicon imposes detrimental constraints on any components formed in advance in the substrate. Actually, the step for the oxidation of the polycrystalline silicon layer requires a thermal treatment which could affect or modify the characteristics of the components. Deterioration may occur under the influence of the temperature but also due to the effect of different dilatations and mechanical stresses resulting therefrom.

The constraints imposed by the steps of the method carried out thus lead to uncertainty as regards the characteristics and the ultimate behavior of the components and are detrimental to the reproducibility of their manufacture.

It is an object of the invention to propose a method of realizing connection means which enables a significant increase of the integration density of electronic circuits on a substrate while reducing their dimensions.

It is notably an object of the invention to reduce the dimensions of the connection means to values which are equal to or smaller than the limits imposed by photolithography techniques.

It is also an object of the invention to propose a method which can be carried out in a reliable, economical and reproducible manner.

Finally, it is an object of the invention to propose a device with an integrated circuit device whose manufacturing method leads to the advantages indicated above.

The technical problems elucidated above are solved by means of a method as claimed in claim 1. The combined dispositions of the steps d and f of the method result in embedded connection means having at least one dimension which is equal to a dimension of the aperture which has been reduced by the thickness of the lateral spacer. When the dimension of the aperture is close to an ultimate etching dimension of the photolithography techniques, the corresponding dimension of the connection means will ultimately be below this limit. The treatment of the step f enables a flat surface to be obtained so that the conductive material is flush with the edge of grooves. The conductor material or materials retained are preferably metals, for example, copper or aluminum.

The method of the invention can be carried out so as to realize different types of connection means. Contact pads represent a first example in this respect. Such pads are in electrical contact with active parts of the substrate, that is, parts which comprise components. In order to realize contact pads, the intermediate layer of dielectric material is etched right through so as to expose the substrate situated below apertures. The apertures then appear, for example, in the form of access wells. Wells traversing a dielectric intermediate layer may also be provided simply to interconnect two layers or two parts of conductive layers situated on each side of the intermediate layer.

The connection means may also take the form of interconnection tracks which interconnect different parts of a circuit or interconnect different contact pads. In order to realize tracks, grooves are etched in the intermediate layer, the course of said grooves corresponding to the course desired for the tracks. The grooves do not necessarily extend right through the intermediate layer.

The invention also relates to an integrated circuit device comprising connection means which are embedded in apertures of a receiving layer and are flush with an edge of the apertures, the apertures having their side-walls covered with insulating lateral spacers. Such a device can be obtained by means of the method described above. In conformity with a special aspect of the realization of the device, the connection means may comprise patterns having at least one dimension smaller than 0.1 μm.

Other characteristics and advantages of the invention will become apparent from the following description which is given with reference to the accompanying Figures which are not drawn to a uniform scale. The following description is given merely by way of a non-limitative, illustrative example.

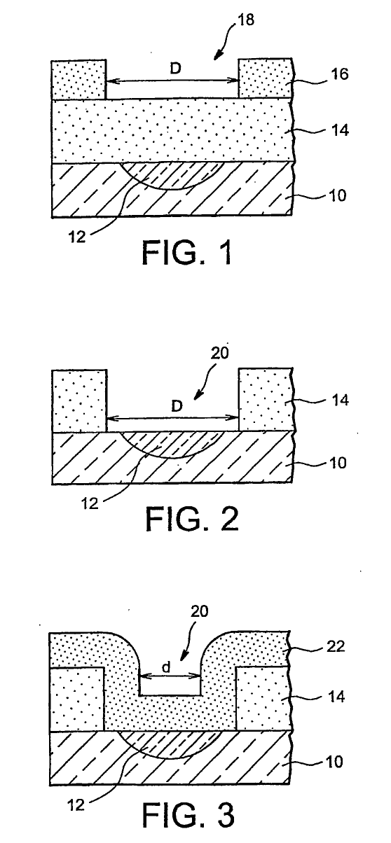

FIG. 1 is a sectional view of a part of a substrate and illustrates a first step of a method of forming connection means;

FIGS. 2, 3 and 4 are sectional views of the part of the substrate of FIG. 1 and illustrate the preparation of a layer of a dielectric material for receiving an electrical conductor material, and

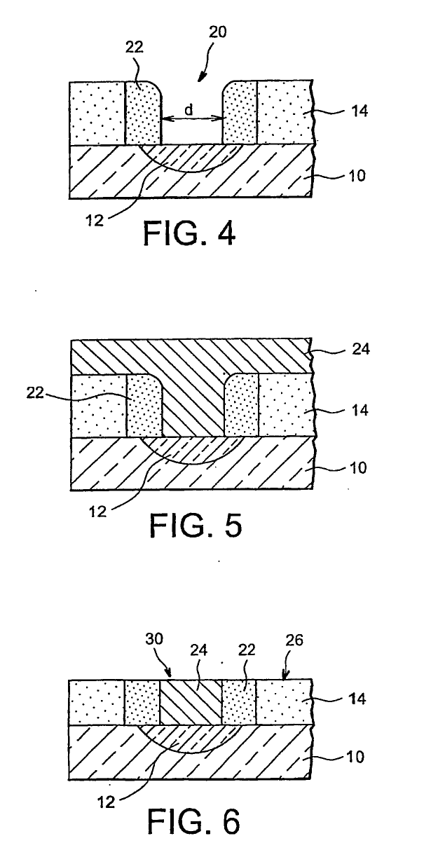

FIGS. 5 and 6 are sectional views of the part of the substrate of FIG. 4 and illustrate the shaping of the electrical conductor material.

The reference numeral 10 in FIG. 1 denotes a substrate such as, for example, a substrate of silicon in which components are formed. For the sake of simplicity, the components are not shown. Merely a doped zone 12 is shown by way of example; this zone may be considered as an active zone of the component or as a part of the component on which a contact is to be realized in the present example.

A first operation, illustrated in FIG. 1, comprises the coating of the substrate with a first layer 14 which will be referred to as the intermediate layer of material 14 hereinafter. More exactly speaking, the intermediate layer of material covers the surface of the substrate with which the doped zone 12 is flush. It is, for example, an intermetal insulating layer (IMD) such as a layer of glass, silicon oxide or a dielectric material; however, this list is not limitative. On the intermediate layer 14 there is formed an etching mask 16 which has one or more windows 18. This is, for example, a mask of a photosensitive resin. The windows 18 define the position or the course of the connection means to be realized. In the example of FIG. 1, the window 18 is situated vertically over the doped zone 12. The window 18 has a dimension, more exactly speaking a diameter D, which is larger than the ultimate dimensions of photolithography which are of the order of magnitude of from 0.1 to 0.14 μm. The dimension D amounts to, for example, 0.2 μm or more and hence does not pose any problems in respect of resolution in lithography.

FIG. 2 illustrates a next step. It comprises the formation, using etching, of one or more apertures 20 which correspond to the windows 18. A single aperture 20 is shown for the sake of simplification. This aperture has at least one dimension, in this case being the diameter D, which is equal to that of the window 18. The etching method is, for example, a selective anisotropic etching method where the etching is stopped on the substrate 10. The use of the substrate as a stop layer for etching enables the exposure of the doped zone 12 on which a contact is to be realized.

FIG. 3 illustrates the step of coating the apertures 20. A layer 22 of a coating material is deposited on the substrate so as to form a substantially uniform layer for coating the surface of the intermediate layer 14, the bottom of the aperture 20 and notably the sides of the intermediate layer 14 in the aperture 20. The layer 22 of coating material is, for example, a layer formed by deposition of an oxide or preferably a layer having a low dielectric constant k. A layer having a low dielectric constant is to be understood to mean a layer whose dielectric constant k is such that: 1<k<3.5. The deposition of such a layer does not necessitate a thermal treatment, for example, as would be necessary so as to carry out a thermal oxidation step according to the state of the art. Therefore, in accordance with the invention the deposition of the coating layer 22 does not induce stresses in the circuit or the substrate.

For the sake of comparison, a thermal oxide as used according to the state of the art (not applied herein because of the described thermal stresses) has a dielectric constant of the order of 4. As materials having a low dielectric constant there may be mentioned, for example, fluorous glass, liquid glass deposited by spinning or also silicon oxide containing carbon. Other materials, such as porous insulating materials, may also be suitable. Thus, the manufacturing process in accordance with the invention does not induce stresses. It is very important that the substrate or wafer is not subject to stresses. This substrate receives several hundreds of integrated circuits on its surface, said circuits subsequently being separated by cutting. If the substrate is subject to stresses due to the manufacturing process, such stresses will be the cause that the performance of the integrated circuits at the center of the substrate will not be the same as that of those at the periphery, so that the manufacturing efficiency is considerably reduced.

FIG. 4 illustrates a next operation. This operation involves etching of an anisotropic type which is continued until all parts of the coating layer 22 which are parallel to the principal surface of the substrate have been removed, that is, the whole layer except for the parts of the coating layer 22 which cover the side-walls of the aperture 20. More exactly speaking, for example, dry etching is performed to eliminate the coating material at the bottom of the aperture 20 and at the surface of the intermediate layer 14 of dielectric material while preserving a part of the coating layer 22 on the side-walls of the aperture 20. At the end of the dry etching operation, the doped zone 12 of the substrate will again be exposed at the bottom of the aperture 20 and the side-walls of the apertures will be coated with the remainder of the coating layer 22. The diameter d of the aperture 18 is thus reduced by an amount equal to double the thickness of the coating layer 22 covering the lateral side-walls of the intermediate layer 14. The part of the coating layer 22 which remains on the side-walls is also referred to as a “lateral spacer”. Its thickness is dependent on the initial thickness of the coating layer 22 as well as on the etching conditions. It amounts to, for example, 0.07 μm. It is used to narrow the aperture 20 at will so that this aperture obtains a new minimized diameter of value d.

FIG. 5 shows the deposition of a metal layer 24 (consisting of copper in the present example) which fills the narrowed aperture 20 of diameter d and covers the free surface of the intermediate layer 14 while forming a substantially uniform external surface. In the narrowed aperture 20 the metal layer 24 fills the volume bounded by the coating layer 22 and has a diameter equal to d.

FIG. 6 illustrates a planing step. The substrate is subjected, for example, to a mechanical-chemical abrasion operation which enables removal of the part of the metal layer 24 which is situated on the principal surface of the intermediate layer 14. The abrasion operation may take be carried out while making a stop on the intermediate layer 14. It may also be continued so as to reduce the thickness of the intermediate layer 14 and that of the metal 24. At the end of this step, the device has a plane surface 26 with which the metal 24 is flush, thus forming a connection pad 30 of minimized diameter d. The intermediate layer 14 and the coating layer 22 are also flush with the surface 26. The connection pad 30, being electrically connected to the doped zone 12, may be connected to other parts of the circuit present on the substrate or outside the substrate. The plane surface 26 may also be advantageously used for the deposition of other layers and for the finishing of the integrated circuit of the substrate. The formation of a conductor track or interconnection track may also take place in the described manner while forming in the intermediate layer an aperture in the form of a groove having such a minimized diameter d.

The method proposed in accordance with the invention not only enables a substantial increase of the integration density, but also significantly improves the manufacturing efficiency of integrated circuits realized on the same substrate or wafer; this is very important considering the fierce industrial competition existing nowadays. This method enables the formation of connections having at least one dimension which is less than 0.1 μm, that is a dimension (d) which is referred to as an “ultimate dimension” and is smaller than can be achieved by means of the masking by photolithography technique in conformity with the step a). The miniaturization of circuits is particularly important for the realization of increasingly smaller devices which require less manufacturing materials and whose manufacture, therefore, produces less pollution. The described method can be used in particular for realizing integrated circuits with a high integration density which is necessary for the industrial manufacture of mobile devices which are referred to as mobile terminals, for example, mobile telephones, wireless communication devices and transmission/receiving devices. This method can also be used for the industrial manufacture of miniaturized electrical or electronic devices, wireless or not, for wide spread use such as clothing telephones or clothing with sensors or information carrying chips, or portable miniaturized sensors for professional use, or portable miniaturized sensors for medical use such as miniaturized medical devices for the detection of health anomalies or protheses, etc.

1. A method of forming electrical connections on a substrate, comprising the following steps:
a) depositing an intermediate layer of material on a substrate,
b) forming an etching mask on the intermediate layer, said mask having at least one window having dimensions which are larger than the dimensions envisaged for the electrical connections to be realized,
c) etching the intermediate layer of material through the window of the mask in order to form therein at least one aperture, having lateral side-walls, for receiving the electrical connections,
d) coating the lateral side-walls of the aperture with a spacer in order to narrow the aperture,
e) depositing at least one conductor material so as to fill the narrowed aperture, and
f) performing an abrasion operation in order to remove excess conductor material outside the narrowed aperture.

2. A method as claimed in claim 1, in which the step a) utilizes a dielectric material for forming the intermediate layer while a metallic conductor material is used in the step e).

3. A method as claimed in claim 1, in which the step d) comprises the deposition of a layer of an insulating coating material, followed by the anisotropic etching of this layer so as to preserve a part thereof on the side-walls of the aperture.

4. A method as claimed in claim 1, in which the side-walls of the aperture are coated by means of a dielectric material having a low dielectric constant (k).

5. A method as claimed in claim 4, in which the dielectric material of the coating layer is chosen from among fluorous glass, glass deposited by spinning and silicon oxide containing carbon.

6. A method as claimed in claim 1, in which the window of the mask registers with at least one active part of the substrate, and in which said active part of the substrate is exposed during the etching of the intermediate layer of material through the window of the mask.

7. A method as claimed in claim 1, in which apertures are etched which extend right through the intermediate layer.

8. A method as claimed in claim 1, in which the mask is formed by means of a photolithography technique, and in which the narrowed apertures have dimensions (d) which are referred to as “ultimate” dimensions which are smaller than those that can be achieved by means of said photolithography technique.

9. A method as claimed in claim 1, in which the electrical connections comprise wiring tracks and/or terminals and/or vias between layers.

10. An integrated circuit device which comprises electrical connections which are embedded in apertures of an intermediate layer which is flush with an edge of the apertures, said apertures having side-walls coated with insulating lateral spacers, the integrated circuit device realized by the method as recited in claim 1.

11. A device as claimed in claim 10, in which the spacers are made of a dielectric material having a low dielectric constant.

12. A device as claimed in claim 10, in which the electrical connections comprise wiring tracks and/or contact pads and/or vias between layers and have at least one dimension which is smaller than 0.1 μm.

13. An electrical or electronic device, wireless or not, comprising at least one integrated circuit device as claimed in claim 10.
